(19) United States
(12) Patent Application Publication
(10) Pub. No.: US 2020/0343464 A1
(43) Pub. Date: Oct. 29, 2020

(54) SOURCE-DRAIN CONDUCTORS FOR ORGANIC TFTS

(71) Applicant: Flexenable Limited, Cambridge (GB)

(72) Inventors: Jan Jongman, Cambridge (GB); Brian Asplin, Cambridge (GB); Joffrey Dury, Cambridge (GB)

(21) Appl. No.: 16/760,558

(22) PCT Filed: Oct. 22, 2018
(86) PCT No.: PCT/EP2018/078914

§ 371 Date: Apr. 30, 2020

(30) Foreign Application Priority Data
Oct. 31, 2017 (GB) 1717992.0

(51) Int. Cl. H01L 51/10; H01L 51/00; H01L 51/05

(52) U.S. Cl. CPC H01L 51/105; H01L 2251/308; H01L 51/0541; H01L 51/0023

(57) ABSTRACT

A technique comprising: forming a first conductor pattern at least partly defining source and/or drain conductors for one or more thin film transistor devices; exposing the conductor pattern to a reactive halogen species; and depositing organic semiconductor channel material directly over the exposed first conductor pattern to provide one or more semiconductor channels between source and drain conductors of the exposed first conductor pattern.

An organic thin-film-transistor device (OTFT) comprises an organic semiconductor channel material between source and drain conductors, which may e.g. comprise an inorganic conductor material.

The inventors for the present application have conducted research into improving the transfer of charge carriers between the source and/or drain conductor and the organic semiconductor channel material.

There is hereby provided a method comprising: forming a first conductor pattern at least partly defining source and/or drain conductors for one or more thin film transistor devices; exposing the conductor pattern to a reactive halogen species; and depositing organic semiconductor channel material directly over the exposed first conductor pattern to provide one or more semiconductor channels between source and drain conductors of the exposed first conductor pattern.

According to one embodiment, exposing the conductor pattern to a reactive halogen species comprises exposing the conductor pattern to a plasma generated in an atmosphere comprising a halogen species.

According to one embodiment, the halogen species comprises a fluoro species such as sulphur hexafluoride.

According to one embodiment, the conductor comprises indium-tin-oxide.

According to one embodiment, the source and drain conductors for the one or more thin film transistor devices are additionally defined by a second conductor pattern, wherein the second conductor pattern comprises a material of higher electrical conductivity than the first conductor pattern.

According to one embodiment, the first conductor pattern comprises a material having a larger work function than the second conductor pattern.

According to one embodiment, the method comprises forming the second conductor pattern by a process comprising forming a conductor layer, and removing portions of the conductor layer; and wherein said removing comprises removing portions of the conductor layer in regions where the source and drain conductors will exist in closest proximity to each other after forming the first conductor pattern.

Embodiments of the description are described in detail hereunder, by way of example only, with reference to the accompanying drawings, in which:

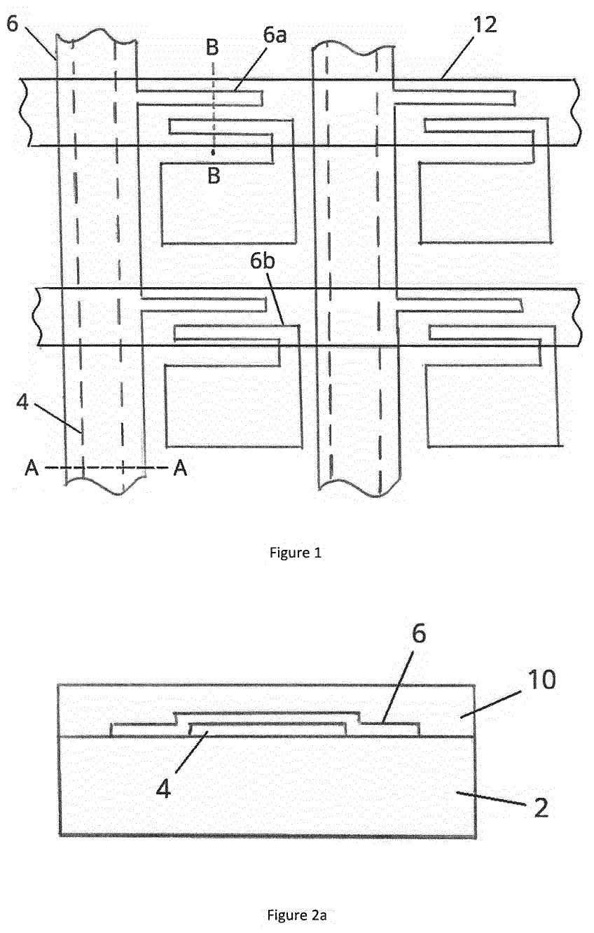

FIG. 1 illustrates an example of a technique according to an embodiment of the present invention;

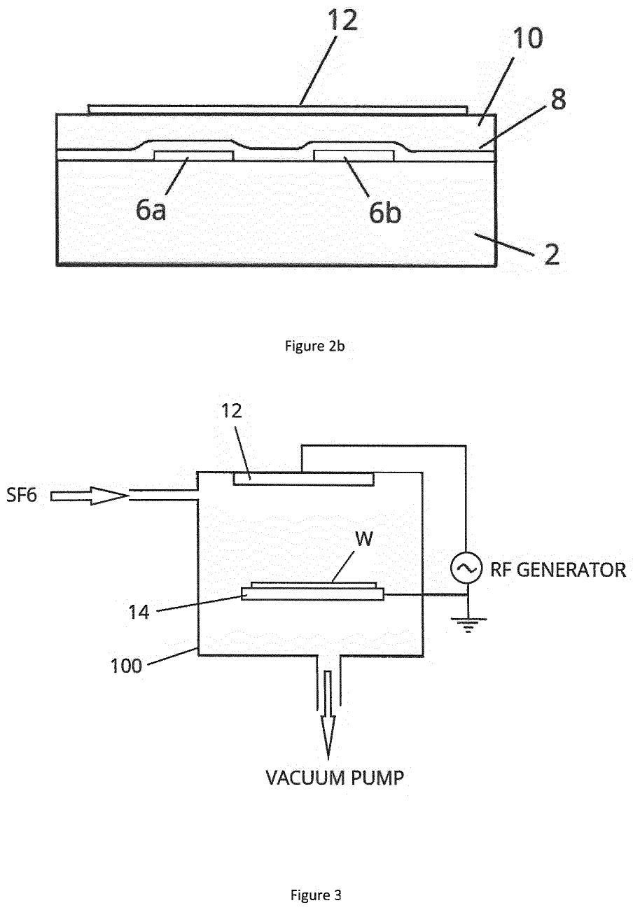

FIGS. 2a and 2b shown cross-sections along lines A-A and B-B, respectively, in FIG. 1; and

FIG. 3 schematically illustrates a plasma system for implementing one step of the technique of FIG. 1.

An embodiment of the present invention is described below for the example of a horizontal TFT having a top-gate design in which the source and drain conductors are at the same level below a gate level, but the same technique is also applicable to TFTs having other designs.

An embodiment of the present invention is described below for the example of an array of organic transistor devices (such as an array of organic thin film transistor (OTFT) device) for the control component for e.g. a display device such as an organic liquid crystal display (OLCD) device, or a sensor device. OTFTs comprise an organic semiconductor (such as e.g. an organic polymer or small-molecule semiconductor) for the semiconductor channels.

A routing pattern 4 is formed on an e.g. organic plastic support film 2 with a planarised surface. In this example, the routing pattern 4 comprises a stack of layers including a bottom layer of Mo, a middle layer of Al, and a top layer of Mo; but the routing pattern 4 may comprise a single layer of highly conductive material, or a different stack of layers comprising at least one layer of a highly conductive material. In this example, the routing pattern 4 is formed by depositing one or more continuous layers over the plastic support film 2, and then patterning the one or more continuous layers by e.g. etching via a photolithographically patterned photoresist mask.

After formation of the routing pattern 4, a pattern of indium-tin-oxide (ITO) is formed. The ITO pattern 6 is aligned with the routing pattern 4, so as to completely cover the routing pattern 4, and additionally provide (a) extensions (fingers) 6a from the routing pattern, and (b) separate finger conductors 6b separated from the extensions 6a by a distance that defines the semiconductor channel length of the TFTs. In this example, the ITO pattern 6 is formed by depositing a continuous layer of ITO, and then patterning the continuous layer of ITO by e.g. etching via a photolithographically patterned photoresist mask.

In this example, the routing pattern 4 and the ITO pattern 6 together form a source-drain conductor pattern defining (i) an array of source conductors, each providing the source conductors for a respective row (or column) of TFTs of an array of TFTs, and extending to a respective terminal for connection to a respective output of a driver chip (not shown); and (ii) a respective drain conductor for each TFT.

The term source conductor refers to the conductor that is connected between the semiconductor channel and a driver chip, and the term drain conductor refers to the conductor that is connected to the driver chip via the semiconductor channel.

In this example, the ITO pattern 6 is designed to completely cover the routing pattern 4 to protect the routing pattern during patterning processes, such as patterning of the ITO continuous layer to form the ITO pattern 6 and/or patterning of a continuous layer of organic semiconductor channel material 8. In this example, the routing pattern 4 is designed to not extend to those regions where the source and drain conductors are in closest proximity (the channel regions) in order to reduce the height (thickness) of the source/drain conductor pattern in these regions, i.e. reduce the height variation of the topographic profile over which the organic semiconductor channel material is deposited, as discussed below.

After formation of the ITO pattern 6, the workpiece (now comprising the source-drain conductor pattern 4, 6 supported on the plastic support film 2) is placed in a plasma chamber, and exposed to a plasma generated in atmosphere comprising sulphur hexafluoride (SF₆). In more detail, the workpiece W was placed in the plasma chamber of a Roth & Rau AK800 reactive ion etch tool. The tool was configured to generate a plasma in the plasma chamber at a SF₆ flow rate of 100 sccm (standard cubic centimetre per minute) with operation of the vacuum pump and a RF power of 500 W; and the workpiece W was exposed to the SF₆ plasma for an exposure time ranging from 10 sec to 10 min. X-ray photoelectron spectroscopy (XPS) measurements indicated the formation of covalent fluorine bonds at the surface of the ITO. Also, after completion of the TFT devices ad discussed below, the on-current Iₒₙ for a given source-drain voltage (source-drain current at the source-drain voltage when an on-bias voltage is applied to the gate) was seen to be greater compared to a control experiment without exposure of the ITO to the SF₆ plasma.

After the plasma treatment, a p-type organic semiconductor material 8, such as a p-type organic polymer semiconductor, is deposited to form semiconductor channels in direct contact with the plasma-treated source/drain conductor pattern. In this example, a continuous layer of organic polymer semiconductor material is deposited over the workpiece, and then patterned (by e.g. etching via a patterned photoresist mask) to form semiconductor islands in the channel regions (where the source and drain conductors are in closest proximity).

A gate dielectric 10 is next formed continuously formed over the workpiece (now comprising the plastic support film 2, source-drain conductor pattern 4, 6 and semiconductor 8) by deposition of one or more layers of one or more organic insulating materials, and a gate conductor pattern 12 is formed over the gate dielectric. The gate conductor pattern defines an array of gate conductors each providing the gate electrode for a respective column (or row) of TFTs, and extending to a respective terminal at the edge of the TFT array for connection to a respective terminal of a gate driver chip. Each TFT is associated with a respective, unique combination of gate and source conductors, such that each TFT can be addressed independently of all other TFTs. The gate conductor pattern may be formed by depositing a layer of conductor material over the gate dielectric 10, and patterning the continuous layer of conductor material by e.g. etching via a patterned photoresist mask.

Further processing of the workpiece may comprise: forming a continuous electrically insulating isolation layer over the workpiece, and patterning the isolation layer to form an array of vias, each extending down to a respective drain conductor of the source/drain conductor pattern; and forming a further conductor pattern over the patterned isolation layer to form an array of pixel conductors each connected to a respective drain conductor via a respective via. The pixel conductors may, for example, form the pixel conductors of a display device, such as a liquid crystal display (LCD) device, an organic light-emitting diode (OLED) device, or an electrophoretic display device.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method comprising: forming a first conductor pattern at least partly defining source and/or drain conductors for one or more thin film transistor devices; exposing the conductor pattern to a reactive halogen species; and depositing organic semiconductor channel material directly over the exposed first conductor pattern to provide one or more semiconductor channels between source and drain conductors of the exposed first conductor pattern.

2. The method according to claim 1, wherein exposing the conductor pattern to a reactive halogen species comprises exposing the conductor pattern to a plasma generated in an atmosphere comprising a halogen species.

3. The method according to claim 2, wherein the halogen species comprises a fluoro species.

4. The method according to claim 1, wherein the conductor comprises indium-tin-oxide.

5. The method according to claim 1, wherein the source and drain conductors for the one or more thin film transistor devices are additionally defined by a second conductor pattern, wherein the second conductor pattern comprises a material of higher electrical conductivity than the first conductor pattern.

6. The method according to claim 5, wherein the first conductor pattern comprises a material having a larger work function than the second conductor pattern.

7. The method according to claim 5, comprising forming the second conductor pattern by a process comprising forming a conductor layer, and removing portions of the conductor layer; and wherein the removing comprises removing portions of the conductor layer in regions where the source and drain conductors will exist in closest proximity to each other after forming the first conductor pattern.

8. The method according to claim 3, wherein the fluoro species comprises sulphur hexafluoride.

9. The method according to claim 2, wherein the conductor comprises indium-tin-oxide.

10. The method according to claim 3, wherein the conductor comprises indium-tin-oxide.

11. The method according to claim 8, wherein the conductor comprises indium-tin-oxide.
